(19) United States
(12) Patent Application Publication
(10) Pub. No.: US 2016/0087227 A1
(43) Pub. Date: Mar. 24, 2016

(54) ORGANIC LIGHT-EMITTING DEVICE

(71) Applicant: SAMSUNG DISPLAY CO., LTD., Yongin-City (KR)

(72) Inventors: Younsun KIM, Yongin-City (KR); Seulong KIM, Yongin-City (KR); Dongwoo SHIN, Yongin-City (KR); Jungsub LEE, Yongin-City (KR); Naoyuki ITO, Yongin-City (KR)

(21) Appl. No.: 14/729,202

(22) Filed: Jun. 3, 2015

(30) Foreign Application Priority Data
Sep. 19, 2014 (KR) 10-2014-0125247

(51) Int. Cl. H01L 51/00

(52) U.S. Cl. CPC H01L 51/0094; H01L 51/0072; H01L 51/0067; H01L 51/0061; H01L 51/0058; H01L 2251/5384; H01L 51/5024

(57) ABSTRACT

An organic light-emitting device including a first electrode, a second electrode facing the first electrode, and an emission layer between the first electrode and the second electrode, the emission layer including a dopant, a first host, and a second host. The dopant is a material emitting delayed fluorescence, the first host is a compound represented by Formula 1 below, and the second host is a compound represented by any one of Formulae 2-1, 2-2, and 2-3 below:

wherein X, X₂, X₃, Y₁ to Y₄, L₁ to L₇, R₁ to R₁₁, a, a₁, a₂, b, b₁, b₂, c, c₁, c₂, d, e, f, and g are as defined in the specification.

### CROSS-REFERENCE TO RELATED APPLICATION

Korean Patent Application No. 10-2014-0125247, filed on Sep. 19, 2014, in the Korean Intellectual Property Office, and entitled: “Organic Light-Emitting Device,” is incorporated by reference herein in its entirety.

### BACKGROUND

1. Field

Embodiments relate to an organic light-emitting device emitting delayed fluorescence.

2. Description of the Related Art

In an organic light-emitting device (OLED), holes provided from an anode and electrons provided from a cathode are recombined in an organic emission layer that is formed between the anode and the cathode, thereby generating light. The OLED has excellent characteristics over excellent color reproducibility, high purity, short response times, self-emission characteristics, thin and light-weight design, high contrast ratios, wide viewing angles, low driving voltages, and low power consumption, so that OLEDs may be widely used in TVs, PC monitors, mobile communication terminals, MP3 players, and navigation devices for mobile vehicles.

A typical OLED includes a substrate and an anode, a hole transport layer, an emission layer, an electron transport layer, and a cathode, which are sequentially stacked on the substrate. When a voltage is applied between the anode and the cathode, holes provided from the anode may be injected to the emission layer through the hole transport layer, and electrons provided from the cathode may be injected to the emission layer through the electron transport layer. The holes and the electrons are recombined in the emission layer region to produce excitons. The excitons are attenuated by radiative decay and emit light having a wavelength corresponding to a band gap of a material for forming the emission layer.

### SUMMARY

Embodiments are directed to an organic light-emitting device including a first electrode, a second electrode facing the first electrode, and an emission layer between the first electrode and the second electrode, the emission layer including a dopant, a first host, and a second host. The dopant is a material emitting delayed fluorescence, the first host is a compound represented by Formula 1 below, and the second host is a compound represented by any one of Formulae 2-1, 2-2, and 2-3 below:

In Formulae 1, 2-1, 2-2, and 2-3,

X is N, S, or O,

X₂ is NR₆, O, or S, and X₃ may be NR₉, O, or S.

Y₁, Y₂, Y₃, and Y₄ are each independently CR₁₂ or N, CR₁₃ or N, CR₁₄ or N, and CR₁₅ or N, and at least one of Y₁, Y₂, Y₃, and Y₄ is N,

R₁ to R₁₅ are each independently selected from a deuterium atom, a halogen atom, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₂-C₂₀ alkenyl group, a C₂-C₂₀ alkynyl group, a C₁-C₂₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₂-C₄₀ heteroaryl group, a C₅-C₄₀ aryloxy group, a C₅-C₄₀ arylthio group, —N(Q₁)(Q₂) (wherein Q₁ and Q₂ are each independently a C₆-C₄₀ aryl group), —P(═O)(Q₃)(Q₄) (wherein Q₃ and Q₄ are each independently a C₆-C₄₀ aryl group), —Si(Q₅)(Q₆)(Q₇) (wherein Q₅, Q₆, and Q₇ are each independently a C₆-C₄₀ aryl group), a C₈-C₄₀ non-aromatic condensed polycyclic group, and a C₂-C₄₀ non-aromatic condensed heteropolycyclic group;

a C₁-C₄₀ alkyl group, a C₂-C₄₀ alkenyl group, a C₂-C₄₀ alkynyl group, and a C₁-C₄₀ alkoxy group, each substituted with at least one of a deuterium atom, a halogen atom, a hydroxyl group, a cyano group, a nitro group, an amino group, an amidino group, a hydrazine group, a hydrazone group, a carboxylic acid or a salt thereof, a sulfonic acid or a salt thereof and a phosphoric acid or a salt thereof, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₅-C₄₀ aryl group, a C₂-C₄₀ heteroaryl group, a C₅-C₄₀ aryloxy group, and a C₅-C₄₀ arylthio group; and

a C₃-C₁₀ cycloalkyl group, a C₃-C₁₀ heterocycloalkyl group, a C₃-C₁ cycloalkenyl group, a C₃-C₁₀ heterocycloalkenyl group, a C₅-C₄₀ aryl group, a C₂-C₄₀ heteroaryl group, a C₈-C₄₀ non-aromatic condensed polycyclic group, a C₂-C₄₀ non-aromatic condensed heteropolycyclic group, a C₅-C₄₀ aryloxy group, and a C₅-C₄₀ arylthio group, each substituted at least one of a deuterium atom, a halogen atom, a hydroxyl group, a cyano group, a nitro group, an amino group, an amidino group, a hydrazine group, a hydrazone group, a carboxylic acid or a salt thereof, a sulfonic acid or a salt thereof and a phosphoric acid or a salt thereof, a C₁-C₂₀ alkyl group, a C₂-C₂₀ alkenyl group, a C₂-C₂₀ alkynyl group, a C₁-C₂₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₅-C₄₀ aryl group, a C₂-C₄₀ heteroaryl group, a C₅-C₄₀ aryloxy group, and a C₅-C₄₀ arylthio group, wherein a plurality of R₂ to R₃ are independent from each other,

L₁ to L₇ are each independently selected from a direct bond, —O—, a C₃-C₁₀ cycloalkylene group, a C₆-C₄₀ arylene group, a C₂-C₄₀ heteroarylene group, a C₈-C₄₀ divalent non-aromatic condensed polycyclic group, a C₂-C₄₀ divalent non-aromatic condensed heteropolycyclic group; and

a C₃-C₁₀ cycloalkylene group, a C₆-C₄₀ arylene group, a C₂-C₄₀ heteroarylene group, a C₈-C₄₀ divalent non-aromatic condensed polycyclic group, a C₂-C₄₀ divalent non-aromatic condensed heteropolycyclic group, each substituted with at least one of a deuterium atom, a halogen atom, a hydroxyl group, a cyano group, a nitro group, an amino group, an amidino group, a hydrazine group, a hydrazone group, a carboxylic acid or a salt thereof, a sulfonic acid or a salt thereof and a phosphoric acid or a salt thereof, a C₁-C₂₀ alkyl group, a C₂-C₂₀ alkenyl group, a C₂-C₂₀ alkynyl group, a C₁-C₂₀ alkoxy group, a C₃-C₁₀ cycloalkyl group, a C₃-C₁₀ heterocycloalkyl group, a C₃-C₁₀ cycloalkenyl group, a C₃-C₁₀) heterocycloalkenyl group, a C₅-C₄₀ aryl group, a C₂-C₄₀ heteroaryl group, a C₅-C₄₀ aryloxy group, and a C₅-C₄₀ arylthio group, wherein a plurality of L₂ to L₃ are independent from each other,

a₁, b₁, and c₁ are each independently an integer of 0 to 3,

a₁ and a₂ are 0 in the case that X is O or S, and a₂ is 1 in the case that X is N,

b and c are each independently an integer of 0 to 4, and

d to g are each independently an integer of 0 to 3.

### BRIEF DESCRIPTION OF THE DRAWINGS

Features will become apparent to those of skill in the art by describing in detail exemplary embodiments with reference to the attached drawings in which:

FIG. 1 illustrates an energy level diagram to explain delayed fluorescence of a light-emitting material; and

FIG. 2 illustrates a schematic view of a structure of an organic light-emitting device according to an embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. Like reference numerals refer to like elements throughout.

As used herein, the term “and/or” includes any and all combinations of one or more of the associated listed items. Expressions such as “at least one of,” when preceding a list of elements, modify the entire list of elements and do not modify the individual elements of the list.

An organic light-emitting device according to embodiments may include a first electrode; a second electrode facing the first electrode; and an emission layer between the first electrode and the second electrode.

The emission layer may include a host and a dopant.

The host may include a first host and a second host.

The first host may be a compound represented by Formula 1 below, and the second host may be a compound represented by any one of Formulae 2-1, 2-2, and 2-3 below.

In Formulae 1, 2-1, 2-2, and 2-3,

X may be N, S, or O,

X₂ may be NR₆, O, or S, and X₃ may be NR₉, O, or S,

Y₁, Y₂, Y₃, and Y₄ may be each independently CR₁₂ or N, CR₁₃ or N, CR₁₄ or N, and CR₁₅ or N, and at least one of Y₁, Y₂, Y₃, and Y₄ may be N,

R₁ to R₁₅ may be each independently selected from a deuterium atom, a halogen atom, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₂-C₂₀ alkenyl group, a C₂-C₂₀ alkynyl group, a C₁-C₂₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₂-C₄₀ heteroaryl group, a C₅-C₄₀ aryloxy group, a C₅-C₄₀ arylthio group, —N(Q₁)(Q₂) (wherein Q₁ and Q₂ may be each independently ₐ C₆-C₄₀ aryl group), —P(═O)(Q₃)(Q₄) (wherein Q₃ and Q₄ may be each independently a C₆-C₄₀ aryl group), —Si(Q₅)(Q₆)(Q₇) (wherein Q₅, Q₆, and Q₇ may be each independently a C₆-C₄₀ aryl group), a C₈-C₄₀ monovalent non-aromatic condensed polycyclic group, and a C₂-C₄₀ monovalent non-aromatic condensed heteropolycyclic group;

a C₁-C₄₀ alkyl group, a C₂-C₄₀ alkenyl group, a C₂-C₄₀ alkynyl group, and a C₁-C₄₀ alkoxy group, each substituted with at least one of a deuterium atom, a halogen atom, a hydroxyl group, a cyano group, a nitro group, an amino group, an amidino group, a hydrazine group, a hydrazone group, a carboxylic acid or a salt thereof, a sulfonic acid or a salt thereof and a phosphoric acid or a salt thereof, a C₃-C₁ cycloalkyl group, a C₃-C₁₀ heterocycloalkyl group, a C₃-C₁₀ cycloalkenyl group, a C₃-C₁₀ heterocycloalkenyl group, a C₅-C₄₀ aryl group, a C₂-C₄₀ heteroaryl group, a C₅-C₄₀ aryloxy group, and a C₅-C₄₀ arylthio group; and

a C₃-C₁₀ cycloalkyl group, a C₃-C₁₀ heterocycloalkyl group, a C₃-C₁₀ cycloalkenyl group, a C₃-C₁₀ heterocycloalkenyl group, a C₅-C₄₀ aryl group, a C₂-C₄₀ heteroaryl group, a C₈-C₄₀ monovalent non-aromatic condensed polycyclic group, a C₂-C₄₀ monovalent non-aromatic condensed heteropolycyclic group, a C₅-C₄₀ aryloxy group, and a C₅-C₄₀ arylthio group, each substituted with at least one of a deuterium atom, a halogen atom, a hydroxyl group, a cyano group, a nitro group, an amino group, an amidino group, a hydrazine group, a hydrazone group, a carboxylic acid or a salt thereof, a sulfonic acid or a salt thereof and a phosphoric acid or a salt thereof, a C₁-C₂₀ alkyl group, a C₂-C₂₀ alkenyl group, a C₂-C₂₀ alkynyl group, a C₁-C₂₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₅-C₄₀ aryl group, a C₂-C₄₀ heteroaryl group, a C₅-C₄₀ aryloxy group, and a C₅-C₄₀ arylthio group,

a plurality of R₂ to R₃ may be independent from each other,

L₁ to L₇ may each independently be selected from a direct bond, —O—, a C₃-C₁₀ cycloalkylene group, a C₆-C₄₀ arylene group, a C₂-C₄₀ heteroarylene group, a C₈-C₄₀ monovalent non-aromatic condensed polycyclic group, a C₂-C₄₀ monovalent non-aromatic condensed heteropolycyclic group; and

a C₃-C₁₀ cycloalkylene group, a C₆-C₄₀ arylene group, a C₂-C₄₀ heteroarylene group, a C₈-C₄₀ divalent non-aromatic condensed polycyclic group, and a C₂-C₄₀ divalent non-aromatic condensed heteropolycyclic group, each substituted with at least one of a deuterium atom, a halogen atom, a hydroxyl group, a cyano group, a nitro group, an amino group, an amidino group, a hydrazine group, a hydrazone group, a carboxylic acid or a salt thereof, a sulfonic acid or a salt thereof and a phosphoric acid or a salt thereof, a C₁-C₂₀ alkyl group, a C₂-C₂₀ alkenyl group, a C₂-C₂₀ alkynyl group, a C₁-C₂₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₅-C₄₀ aryl group, a C₂-C₄₀ heteroaryl group, a C₅-C₄₀ aryloxy group, and a C₅-C₄₀ arylthio group, and a plurality of L₂ and L₃ are each independent,

a₁, b₁, and c₁ may each independently be an integer of 0 to 3,

a₁ and a₂ may be 0 in the case that X is O or S, and a₂ may be 1 in the case that X is N,

b and c may be each independently an integer of 0 to 4, and

d to g may be each independently an integer of 0 to 3.

R₁ to R₁₁ may be each independently selected from

a methyl group, an ethyl group, a propyl group, a butyl group, a pentyl group, a hexyl group, a heptyl group, a pyrrolyl group, a furyl group, a pyrazolyl group, an imidazolyl group, an oxazolyl group, an isoxazolyl group, a triazolyl group, a tetrazolyl group, an oxadiazolyl group, a pyridyl group, a pyrimidinyl group, a pyrazinyl group, a pyridazinyl group, a triazinyl group, a pyranyl group, a thiophenyl group, a thiazolyl group, an isothiazolyl group, a thiopyranyl group, an indolyl group, an isoindolyl group, an indolizinyl group, a benzofuryl group, an isobenzofuryl group, an indazolyl group, a benzimidazolyl group, a benzoxazolyl group, a benzisoxazolyl group, an imidazopyridyl group, a purinyl group, a quinolyl group, an isoquinolyl group, a phthalazinyl group, a quinazolinyl group, a quinoxalinyl group, a naphthyridinyl group, a cinnolinyl group, a benzothiophenyl group, a benzothiazolyl group, a carbazolyl group, a benzocarbazolyl group, a pyridoindolyl group, a dibenzofuryl group, a phenanthridinyl group, a benzoquinolyl group, a phenazinyl group, a dibenzosilolyl group, a dibenzothiophenyl group, a benzocarbazolyl group, —N(Q₁)(Q₂) (wherein Q₁ and Q₂ may be each independently a C₆-C₄₀ aryl group), —N(Q₁)(Q₂) (wherein Q₁ and Q₂ may be each independently a C₆-C₄₀ aryl group), —P(═O)(Q₃)(Q₄) (wherein Q₃ and Q₄ may be each independently a C₆-C₄₀ aryl group), —Si(Q₅)(Q₆)(Q₇) (wherein Q₅, Q₆, and Q, may be each independently a C₆-C₄₀ aryl group), a C₈-C₄₀ monovalent non-aromatic condensed polycyclic group, and a C₂-C₄₀ monovalent non-aromatic condensed heteropolycyclic group;

a methyl group, an ethyl group, a propyl group, a butyl group, a pentyl group, a hexyl group, a heptyl group, an octyl group, a nonyl group, and a decyl group, each substituted with at least one of a deuterium atom, a halogen atom, a hydroxyl group, a cyano group, a nitro group, an amino group, a C₆-C₄₀ aryl group, and a C₆-C₄₀ heteroaryl group; and

a pyrrolyl group, a furyl group, a pyrazolyl group, an imidazolyl group, an oxazolyl group, an isoxazolyl group, a triazolyl group, a tetrazolyl group, an oxadiazolyl group, a pyridyl group, a pyrimidinyl group, a pyrazinyl group, a pyridazinyl group, a triazinyl group, a pyranyl group, a thiophenyl group, a thiazolyl group, an isothiazolyl group, a thiopyranyl group, an indolyl group, an isoindolyl group, an indolizinyl group, a benzofuryl group, an isobenzofuryl group, an indazolyl group, a benzimidazolyl group, a benzoxazolyl group, a benzisoxazolyl group, an imidazopyridyl group, a purinyl group, a quinolyl group, an isoquinolyl group, a phthalazinyl group, a quinazolinyl group, a quinoxalinyl group, a naphthyridinyl group, a cinnolinyl group, a benzothiophenyl group, a benzothiazolyl group, a carbazolyl group, a benzocarbazolyl group, a pyridoindolyl group, a dibenzofuryl group, a phenanthridinyl group, a benzoquinolyl group, a phenazinyl group, a dibenzosilolyl group, a dibenzothiophenyl group, a benzocarbazole group, —N(Q₁)(Q₂) (wherein Q₁ and Q₂ may be each independently a C₆-C₄₀ aryl group), —P(═O)(Q₃)(Q₄) (wherein Q₃ and Q₄ may be each independently a C₆-C₄₀ aryl group), —Si(Q₅)(Q₆)(Q₇) (wherein Q₅, Q₆ and Q₇ may be each independently a C₆-C₄₀ aryl group), a C₈-C₄₀ monovalent non-aromatic condensed polycyclic group, and a C₂-C₄₀ monovalent non-aromatic condensed heteropolycyclic group, each substituted with at least one of a deuterium atom, a halogen atom, a hydroxyl group, a cyano group, a nitro group, an amino group, a carboxylic acid or a salt thereof, a sulfonic acid or a salt thereof and a phosphoric acid or a salt thereof, a C₁-C₁₀ alkyl group, a C₂-C₁₀ alkenyl group, a C₂-C₁₀ alkynyl group, a C₁-C₁₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₃₀ aryl group, a C₄-C₃₀ heteroaryl group, a C₅-C₃₀ aryloxy group, a C₅-C₃₀ arylthio group, —Si(Q₃₁)(Q₃₂)(Q₃₃) (wherein Q₃₁ to Q₃₃ may be each independently selected from a hydrogen, a C₁-C₁₀ alkyl group, a C₁-C₁₀ alkoxy group, and a C₆-C₂₀ aryl group).

In some embodiments, R₁ to R₁₁ may be each independently selected from —N(Q₁)(Q₂) (wherein Q₁ and Q₂ may be a phenyl group or a phenyl group substituted with a C₆-C₄₀ aryl group) and groups represented by Formulae 3A to 3O below:

In Formulae 3A to 3O.

Z₁₁ to Z₁₈ may each independently be a deuterium atom, a halogen atom, a hydroxyl group, a cyano group, a nitro group, an amino group, a carboxylic acid or a salt thereof, a sulfonic acid or a salt thereof and a phosphoric acid or a salt thereof, a C₁-C₂₀ alkyl group, a C₁-C₂₀ alkoxy group, a C₆-C₄ aryl group, a C₂-C₄₀ heteroaryl group, a C₈-C₄₀ monovalent non-aromatic condensed polycyclic group, and a C₂-C₄₀ monovalent non-aromatic condensed heteropolycyclic group;

a C₁-C₂₀ alkyl group and a C₁-C₂₀ alkoxy group, each substituted with at least one of a deuterium atom and a halogen atom; and

a C₆-C₄₀ aryl group, a C₂-C₄₀ heteroaryl group, a C₈-C₄₀ monovalent non-aromatic condensed polycyclic group, and a C₂-C₄₀ monovalent non-aromatic condensed heteropolycyclic group, each substituted with at least one of a deuterium atom, a halogen atom, C₁-C₂₀ alkyl group, a C₁-C₂₀ alkoxy group, a C₆-C₂₀ aryl group, and a C₂-C₂₀ heteroaryl group;

Ar₁ to Ar₉ may be each independently selected from

a C₆-C₄₀ aryl group and a C₂-C₄₀ heteroaryl group; and

a C₆-C₄₀ aryl group and C₂-C₄₀ heteroaryl group, each substituted with at least one of a deuterium atom, a halogen atom, a C₁-C₂₀ alkyl group, a C₁-C₂₀ alkoxy group, a C₆-C₂₀ aryl group, a C₂-C₂₀ heteroaryl group, a C₈-C₄₀ monovalent non-aromatic condensed polycyclic group, a C₂-C₄₀ monovalent non-aromatic condensed heteropolycyclic group, —N(Q₁)(Q₂) (wherein Q₁ and Q₂ are each independently a C₆-C₄₀ aryl group);

Ar₁ and Ar₂ may be connected with each other to form a condensed ring;

p1 to p3 may be each independently an integer of 0 to 4,

p4 may be an integer of 0 to 5,

p5 may be an integer of 0 to 4,

p6 may be an integer of 0 to 4,

p7 may be an integer of 0 to 3, and

* indicates a binding site.

For example, Z₁ to Z₁₈ may each independently be selected from a cyano group, a methyl group, an ethyl group, a t-butyl group, a phenyl group, and a naphthyl group.

For example, Ar₁ to Ar₉ may be each independently selected from a phenyl group, a dibenzofuryl group, and a dibenzothiophenyl group; and

a phenyl group, a dibenzofuryl group, and a dibenzothiophenyl group, each substituted with at least one of —NQ₁Q₂ (wherein Q₁ and Q₂ are each independently a C₆-C₄₀ aryl group), a C₆-C₄₀ heteroaryl group, a C₈-C₄₀ monovalent non-aromatic condensed polycyclic group, and a C₂-C₄₀ monovalent non-aromatic condensed heteropolycyclic group. Here, Ar₁ and Ar₂ may be connected with each other to form a condensed ring.

For example, R₁ to R₁₁ may each independently be selected from groups represented by Formulae 4A to 4AI below:

wherein * indicates a binding site.

L₁ to L₇ may be each independently selected from cyclobutylene, adamantylene, phenylene, pentalenylene, indenylene, naphthylene, azulenylene, heptalenylene, indacenylene, acenaphthylene, fluorenylene, spiro-fluorenylene, benzofluorenylene, dibenzofluorenylene, phenalenylene, phenanthrenylene, anthracenylene, fluoranthenylene, triphenylenylene, pyrenylene, chrysenylene, naphthacenylene, picenylene, perylenylene, pentaphenylene, hexacenylene, pentacenylene, rubicenylene, coronenylene, ovalenylene, pyrrolylene, thiophenylene, furanylene, imidazolylene, pyrazolylene, thiazolylene, isothiazolylene, oxazolylene, isooxazolylene, pyridylene, pyrazinylene, pyrimidinylene, pyridazinylene, isoindolylene, indolylene, indazolylene, purinylene, quinolinylene, isoquinolinylene, benzoquinolinylene, phthalazinylene, naphthyridinylene, quinoxalinylene, quinazolinylene, cinnolinylene, carbazolylene, phenanthridinylene, acridinylene, phenanthrolinylene, phenazinylene, benzoimidazolylene, benzofuranylene, benzothiophenylene, isobenzothiazolylene, benzooxazolylene, isobenzooxazolylene, triazolylene, tetrazolylene, oxadiazolylene, triazinylene, dibenzofuranylene, dibenzothiophenylene, benzocarbazolylene, dibenzocarbazolylene, thiadiazolylene, and imidazopyridylene; and

phenylene, pentalenylene, indenylene, naphthylene azulenylene, heptalenylene, indacenylene, acenaphthylene, fluorenylene, spiro-fluorenylene, benzofluorenylene, dibenzofluorenylene, phenalenylene, phenanthrenylene, anthracenylene, fluoranthenylene, triphenylenylene, pyrenylene, chrysenylene, naphthacenylene, picenylene, perylenylene, pentaphenylene, hexacenylene, pentacenylene, rubicenylene, coronenylene, ovalenylene, pyrrolylene, thiophenylene, furanylene, imidazolylene, pyrazolylene, thiazolylene, isothiazolylene, oxazolylene, isoxazolylene, pyridylene, pyrazinylene, pyrimidinylene, pyridazinylene, isoindolylene, indolylene, indazolylene, purinylene, quinolinylene, isoquinolinylene, benzoquinolinylene, phthalazinylene, naphthyridinylene, quinoxalinylene, quinazolinylene, cinnolinylene, carbazolylene, phenanthridinylene, acridinylene, phenanthrolinylene, phenazinylene, benzoimidazolylene, benzofuranylene, benzothiophenylene, isobenzothiazolylene, benzooxazolylene, isobenzooxazolylene, triazolylene, tetrazolylene, oxadiazolylene, triazinylene, dibenzofuranylene, dibenzothiophenylene, benzocarbazolylene, dibenzocarbazolylene, thiadiazolylene, and imidazopyridylene, each substituted with at least one of a deuterium atom, a halogen atom, a hydroxyl group, a cyano group, an amino group, a C₁-C₂₀ alkyl group, a C₂-C₂₀ alkenyl group, a C₂-C₂₀ alkynyl group, a C₁-C₂₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₅-C₄₀ aryl group, a C₂-C₄₀ heteroaryl group, a C₅-C₄₀ aryloxy group, and a C₅-C₄₀ arylthio group.

In some embodiments, L₁ to L₆ may be each independently selected from groups represented by Formulae 5A to 5D below:

In Formulae 5A to 5D,

Z₂₁ to Z₂₅ may be each independently selected from a deuterium atom, a halogen atom, a hydroxyl group, a cyano group, a nitro group, an amino group, a carboxylic acid or a salt thereof, a sulfonic acid or a salt thereof and a phosphoric acid or a salt thereof, a C₁-C₂₀ alkyl group, a C₁-C₂₀ alkoxy group, a C₆-C₄₀ aryl group, a C₂-C₄₀ heteroaryl group, a C₈-C₄₀ monovalent non-aromatic condensed polycyclic group, and a C₂-C₄₀ monovalent non-aromatic condensed heteropolycyclic group;

a C₁-C₂₀ alkyl group and a C₁-C₂₀ alkoxy group, each substituted with at least one of a deuterium atom and a halogen atom; and

a C₆-C₄₀ aryl group, a C₂-C₄₀ heteroaryl group, a C₈-C₄₀ monovalent non-aromatic condensed polycyclic group, and a C₂-C₄₀ monovalent non-aromatic condensed heteropolycyclic group, each substituted with at least one of a deuterium atom, a halogen atom, C₁-C₂₀ alkyl group, a C₁-C₂₀ alkoxy group, a C₆-C₂₀ aryl group, and a C₂-C₂₀ heteroaryl group;

q1 may be an integer of 0 to 4,

q2 may be an integer of 0 to 3,

q3 may be an integer of 0 to 2,

q4 and q5 may be each independently an integer of 0 to 5, and

* indicates a binding site.

For example, Z₂₁ to Z₂₅ may each independently be or include a methyl group or a carbazolyl group.

For example, L₁ to L₇ may be each independently selected from groups represented by Formulae 6A to 6I below:

wherein * indicates a binding site.

The condensed cyclic compound represented by Formula 1 above may be any one of Compounds below, as examples:

The condensed cyclic compound represented by Formula 2-1 above may be any one of Compounds below, as examples:

The condensed cyclic compound represented by Formula 2-2 above may be any one of Compounds below, as examples:

The condensed cyclic compound represented by Formula 2-3 above may be any one of Compounds below, as examples:

A weight ratio of the first host and the second host may be in a range of about 10:90 to about 90:10. In addition, an amount of the dopant in the emission layer may be in a range of about 0.01 parts to about 30 parts by weight based on the total weight of the emission layer.

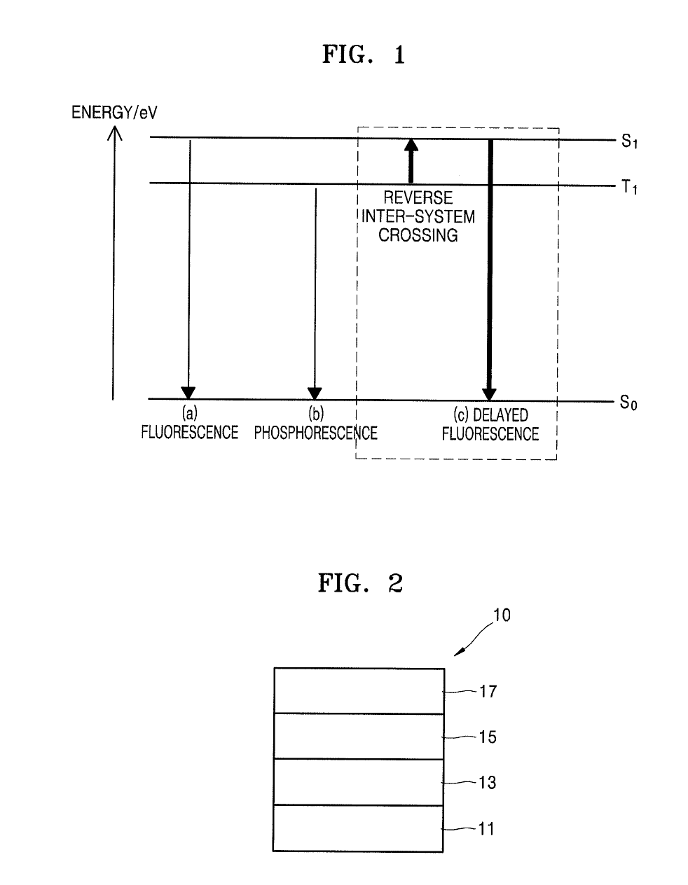

FIG. 1 illustrates an energy level diagram showing a ground state energy level S₀, a triplet energy level T₁, and a singlet energy level S₁ of a luminescent material. In FIG. 1. (a) indicates fluorescent emission occurring when the singlet energy level S₁ is converted into the ground state energy level S₀ while energy is lost in the form of light, (b) indicates phosphorescent emission occurring when the triplet energy level T₁ is converted into the ground state energy level S₀, while energy is lost in the form of light; and (c) indicates delayed fluorescent emission occurring when the singlet energy level S₁, which is populated by an upconversion energy transfer (reverse inter-system crossing) from the triplet energy level T₁ to the singlet energy level S₁, is converted into the ground state energy level S₀.

The dopant may be a compound represented by any one of Formulae 3-1, 3-2, 3-3, and 3-4 below:

[EDG]ₘ-{Aₙ-[EWG]ₒ}ₚ <Formula 3-1>

[EWG]_{q}-{Aᵣ-[EDG]ₛ}ₜ <Formula 3-2>

[EWG]-A-[EDG]-B-[EWG] <Formula 3-3>

[EDG]-A-[EWG]-B-[EDG] <Formula 3-4>

An electron donating group (EDG) may refer to a functional group that provides electron donation effects through an electron pair in a it orbital or an unshared electron pair. For example, the EDG may include —C≡C—R, —O—R, —N(R)H, —N(R)₂, —NH₂, —OH or —NH(CO)—R, a C₆-C₃₀ aryl group, a substituted or unsubstituted C₆-C₃₀ monomer non-aromatic condensed polycyclic group, a furanyl group or a derivative thereof, a benzofuranyl group or a derivative thereof, a dibenzofuranyl group or a derivative thereof, a thiophenyl group or a derivative thereof, a benzothiophenyl group or a derivative thereof, a dibenzothiophenyl group or a derivative thereof, a fluorenyl group or a derivative thereof, a spiro-fluorenyl group or a derivative thereof, or an indenyl group or a derivative thereof. In addition, the EDG may include a substituted or unsubstituted C₁-C₂₀ alkyl group.

An electron withdrawing group (EWG) may refer to a functional group that may provides electron withdrawing effects through an element having higher electronegativity than carbon or that forms a partially positive charge. For example, the EWG may be an electron transporting group selected from —X(—F, —Cl, —Br, —I), —C(═O)H, —C(═O)—R, —C(═O)O—R, —C(═O)OH, —(C═O)Cl, —CF₃, —C≡N, —S(═O)₂—OH, —S(═O)₂—O—R, —N⁺H₃, —N⁺R₃, —(N⁺═O)═O⁻, a substituted or unsubstituted N-containing 5-membered ring group of a C₂-C₃₀ group, a substituted or unsubstituted N-containing 6-membered ring group of a C₂-C₃₀ group, a substituted or unsubstituted N-containing 5-membered group of a C₁₀-C₃₀ group that is fused with a 6-membered ring, and a substituted or unsubstituted N-containing 6-membered ring of a C₁₀-C₃₀ group that is fused with a 6-membered ring.

Here, R may be each independently selected from a hydrogen, a deuterium atom, a C₆-C₃₀ aryl group, and a C₂-C₃₀ heteroaryl group; and a C₆-C₃₀ aryl group or a C₂-C₃₀ heteroaryl group, each substituted with a C₁-C₁₀ alkyl group, a C₁-C₁₀ alkoxy group, a C₆-C₃₀ aryl group, a C₂-C₃₀ heteroaryl group, a C₆-C₃₀ aryloxy group, or a C₆-C₃₀ arylthio group.

In Formulae 3-1 to 3-4 above, A and B are linking groups that link the EDG and the EWG. For example, A and B may be a single bond, a C₁-C₃₀ alkylene group, or a C₆-C₃₀ arylene group.

In Formulae 3-1 to 3-4 above, m, q, o, s, p, and t may be integers of 1 to 10, and n and r may be 0 or 1.

Examples of the condensed cyclic compound represented by any one of Formulae 3-1 to Formula 3-4 are as below:

The first host represented by Formula 1 above may be a host having a hole-transporting unit with a high triplet energy level, and the second host represented by Formulae 2-1, 2-2 or 3 above may be a host including an electron-transporting unit with a high triplet energy level.

The first host may have a high triplet energy level and accordingly, may have high efficiency. The second host may have excellent lifespan characteristics and may be capable of controlling the triplet energy level or mobility by, for example, controlling substituents. Thus, use of a mixed host of the first host and the second host may provide an organic light-emitting device with excellent efficiency and lifespan characteristics.

Hereinafter, an organic light-emitting device including an emission layer according to the current embodiment will be explained in detail.

FIG. 2 illustrates a schematic view of a structure of an organic light-emitting device 10 according to an embodiment.

Referring to FIG. 2, the organic light-emitting device 10 may include a substrate 11 and a first electrode 13, an organic layer 15, and a second electrode 17, which are sequentially stacked on the substrate 11.

For use as the substrate 11, any suitable substrate for a organic light-emitting device may be used. For example, the substrate 11 may be a glass substrate or transparent plastic substrate, each of which has excellent mechanical strength, thermal stability, transparency, surface smoothness, ease of handling, and water-proof properties.

The first electrode 13 may be formed by, for example, depositing or sputtering a material for forming a first electrode, on the substrate 11. When the first electrode 13 is an anode, the material for forming the first electrode may be selected from materials with a high work function to facilitate hole injection. The first electrode 13 may be a transmissive electrode or a semi-transmissive electrode. The material for forming the first electrode 13 may have characteristics of excellent transparency and conductivity. Examples thereof include indium tin oxide (ITO), indium zinc oxide (IZO), tin oxide (SnO₂), and zinc oxide (ZnO). In other implementations, the material for forming the first electrode 13 may be magnesium (Mg), silver (Ag), aluminum (Al), aluminum:lithium (Al:Li), calcium (Ca), Ag:ITO, Mg:indium (In), or Mg:Ag, which may be used to form a reflective electrode for use as the first electrode 13. The first electrode 13 may have a single-layer structure or a multi-layer structure consisting two or more different layers. For example, the first electrode 13 may have a three-layered structure of ITO/Ag/ITO.

The organic layer 15 may be disposed on the first electrode 13.

The organic layer 15 may include a hole transport region, an emission layer, and an electron transport region.

The hole transport region may include at least one of a hole injection layer, a hole transport layer, and an electron blocking layer. The electron transport region may include an electron injection layer, an electron transport layer, and a hole blocking layer.

A hole injection layer (HIL) may be formed on the first electrode 13 by using various methods, such as vacuum deposition, spin coating, casting, and Langmuir-Blodgett (LB) deposition.

When the HIL is formed by vacuum deposition, deposition conditions for forming the HIL may vary according to a compound used to form the HIL, a structure of the HIL, and thermal characteristics of the HIL. For example, the deposition conditions may include a deposition temperature in a range of about 100° C. to about 500° C., vacuum pressure in a range of about 10⁻⁸ torr to about 10⁻³ torr, and a deposition rate in a range of about 0.01 Å/sec to about 100 Å/sec.

When the HIL is formed by spin coating, spin coating conditions for forming the HIL may vary according to a compound used to form the HIL, a structure of the HIL, and thermal characteristics of the HIL. For example, the spin coating conditions may include a coating speed in a range of about 2,000 rpm to about 5,000 rpm, and a temperature at which a heat treatment is performed to remove a solvent may be in a range of about 80° C. to about 200° C.

A suitable hole injection material may be used as a material for forming the HIL Examples thereof include a phthalocyanine compound, such as copper phthalocyanine, N,N′-diphenyl-N,N′-bis-[4-(phenyl-m-tolyl-amino)-phenyl]-biphenyl-4,4′-diamine (DNTPD), 4,4′,4″-tris(3-methylphenylphenylamino) triphenylamine (m-MTDATA). 4,4′4″-Tris(N,N-diphenylamino)triphenylamine) (TDATA), 4,4′,4″-tris {N,-(2-naphthyl)-N-phenylamino)}-triphenylamine (2T-NATA). N,N′-bis(naphthalen-1-yl)-N,N′-bis(phenyl)-2,2′-dimethylbenzidine (α-NPD), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonicacid (PANI/CSA), or polyaniline)/poly(4-styrenesulfonate) (PANI/PSS).

A thickness of the HIL may be in a range of about 100 Å to about 10,000 Å, e.g., about 100 Å to about 1,000 Å. When the thickness of the HIL is within these ranges, satisfactory hole injecting characteristics may be obtained without a substantial increase in driving voltage.

A hole transport layer (HTL) may be formed on the HIL by using a suitable method, such as vacuum deposition, spin coating, casting, and LB. When the HTL is formed by vacuum deposition and spin coating, deposition and coating conditions for forming the HTL may vary according to a compound used to form the HTL, but in general, may be determined by referring to the deposition and coating conditions for forming the HIL.

A suitable hole transport material may be used as a material for forming the HTL. Examples thereof include a carbazole derivative, such as N-phenylcarbazole or polyvinyl carbazole, a triphenylamine-based material, such as N,N′-bis(3-methylphenyl)-N,N′-diphenyl-[1,1-biphenyl]-4,4′-diamine (TPD), N,N′-bis(naphthalen-2-yl)-N,N′-bis(phenyl)-benzidine (NPB), N,N′-bis(naphthalen-1-yl)-N,N′-bis(phenyl)-2,2′-dimethylbenzidine (α-NPD), or 4,4′,4″-tris(N-carbazolyl)triphenylamine (TCTA).

A thickness of the HTL may be in a range of about 50 Å to about 1,000 Å, e.g., about 100 Å to about 800 Å. When the thickness of the HTL is within these ranges, satisfactory hole transporting characteristics may be obtained without a substantial increase in driving voltage.

In some implementations, a hole injection-transport layer may be formed, instead of the HIL and the HTL. The hole injection-transport layer may include at least one material selected from the materials for forming the HIL and the HTL described above. A thickness of the hole injection-transport layer may be in a range of about 500 Å to about 10,000 Å, e.g., about 100 Å to about 1,000 Å. When the thickness of the hole injection-transport layer is within these ranges, satisfactory hole injection and transporting characteristics may be obtained without a substantial increase in driving voltage.

At least one layer of the HIL, the HTL, and the hole injection-transport layer may include at least one compound represented by Formula 100 below and a compound represented by Formula 101 below:

In Formula 100, Ar₁₀₁ and Ar₁₀₂ may be each independently a substituted or unsubstituted C₆-C₄₀ arylene group. For example, Ar₁₀₁ and Ar₁₀₂ may each independently be a phenylene group, a pentalenylene group, an indenylene group, a naphthylene group, an azulenylene group, a heptalenylene group, a substituted or unsubstituted acenaphthylene group, a fluorenylene group, a phenalenylene group, a phenanthrenylene group, an anthrylene group, a fluoranthenylene group, a triphenylenylene group, a pyrenylene group, a chrysenylene group, a naphthacenylene group, a picenylene group, a perylenylene group, and a pentacenylene group; and

a phenylene group, a pentalenylene group, an indenylene group, a naphthylene group, an azulenylene group, a heptalenylene group, a substituted or unsubstituted acenaphthylene group, a fluorenylene group, a phenalenylene group, a phenanthrenylene group, an anthrylene group, a fluoranthenylene group, a triphenylenylene group, a pyrenylene group, a chrysenylene group, a naphthacenylene group, a picenylene group, a perylenylene group, and a pentacenylene group, each of which substituted with at least one of a deuterium atom, a halogen atom, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₄₀ alkyl group, a C₂-C₄₀ alkenyl group, a C₂-C₄₀ alkynyl group, a C₁-C₄₀ alkoxy group, a C₃-C₁₀ cycloalkyl group, a C₃-C₁₀ cycloalkenyl group, a C₃-C₁₀ heterocycloalkyl group, a C₃-C₁₀ heterocycloalkenyl group, a C₆-C₄₀ aryl group, a C₆-C₄₀ aryloxy group, a C₆-C₄₀ arylthio group, and a C₂-C₄₀ heteroaryl group.

In Formula 100, a and b may be each independently an integer of 0 to 5, or may be each independently 0, 1, or 2. For example, a may be 1 and b may be 0.

In Formulae 100 and 101, R₁₀₁ to R₁₂₂ may each independently be a hydrogen atom, a deuterium atom, a halogen atom, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a substituted or unsubstituted C₁-C₄₀ alkyl group, a substituted or unsubstituted C₂-C₄₀ alkenyl group, a substituted or unsubstituted C₂-C₄₀ alkynyl group, a substituted or unsubstituted C₁-C₄₀ alkoxy group, a substituted or unsubstituted C₃-C₄₀ cycloalkyl group, a substituted or unsubstituted C₆-C₄₀ aryl group, a substituted or unsubstituted C₆-C₄₀ aryloxy group, or a substituted or unsubstituted C₆-C₄₀ arylthio group.

For example, R₁₀₁ to R₁₀₈ and R₁₁₀ to R₁₂₂ may each independently be one of a hydrogen, a deuterium atom, a halogen atom, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₁₀ alkyl group (e.g., a methyl group, an ethyl group, a propyl group, a butyl group, a pentyl group, or a hexyl group), a C₁-C₁₀ alkoxy group (e.g., a methoxy group, an ethoxy group, a propoxy group, a butoxy group, or a pentoxy group), a phenyl group, a naphthyl group, an anthryl group, a fluorenyl group, a pyrenyl group; and

a C₁-C₁₀ alkyl group, a C₁-C₁₀ alkoxy group, a phenyl group, a naphthyl group, an anthryl group, a fluorenyl group, and a pyrenyl group, each substituted with at least one of a deuterium atom, a halogen atom, a hydroxyl group, a cyano group, a nitro group, an amino group, an amidino group, a hydrazine group, a hydrazone group, a carboxylic acid or a salt thereof, a sulfonic acid or a salt thereof, and a phosphoric acid or a salt thereof.

In Formula 100, R₁₀₉ may be at least one of a phenyl group, a naphthyl group, an anthryl group, a biphenyl group, a pyridyl group; and

a phenyl group, a naphthyl group, an anthryl group, a biphenyl group, and a pyridyl group, each substituted with at least one of a deuterium atom, a halogen atom, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a substituted or unsubstituted C₁-C₂₀ alkyl group, and a substituted or unsubstituted C₁-C₂₀ alkoxy group.

According to an embodiment, the compound represented by Formula 100 above may be represented by Formula 100A below:

In Formula 100A, R₁₀₈, R₁₀₉, R₁₁₇, and R₁₁₈ may be understood by referring to the description provided herein.

For example, at least one layer of the HIL, HTL, and the hole injection-transport layer may include at least one of Compounds 102 to 121 below:

At least one of the HIL, the HTL, and the hole injection-transport layer may further include a charge-generation material for the improvement of conductive characteristics of films, in addition to a known material for forming the HIL, a known material for forming the HTL, and/or a known material having both hole injection and hole transport capabilities.

The charge-generation material may be, e.g., a p-dopant. Examples of the p-dopant include a quinone derivative, such as tetracyanoquinodimethane (TCNQ) and tetrafluorotetracyanoquinodimethane (F4-TCNQ) quinone; a metal oxide, such as a tungsten oxide and a molybdenum oxide; and Compound hATCN (1,4,5,8,9,11-hexaazatriphenylene-hexacarbonitrile) below.

When the HIL, the HTL, or the hole injection-transport layer further includes the charge-generation material, the charge-generation material may be homogeneously dispersed or non-homogeneously distributed in the layers.

An emission layer (EML) may be formed on the HTL or the hole injection-transport layer by using various methods, such as vacuum deposition, spin coating, casting, and LB deposition. When the EML is formed by vacuum deposition and spin coating, deposition conditions for forming the EML may vary according to a compound used to form the EML, and in general, may be determined by referring to deposition and coating conditions for forming the HIL.

The emission layer may include the first host, the second host, and the dopant emitting delayed fluorescence.

The compound of Formula 1 according to the aforementioned embodiment in connection with the emission layer may be used as the first host. The compound of Formulae 2-1, 2-2, or 3 according to the aforementioned embodiment in connection with the emission layer may be used as the second host. In addition, compound of Formulae 3-1, 3-2, 3-3, or 3-4 according to the aforementioned embodiment in connection with the emission layer may be used as the dopant emitting the delayed fluorescence.

When the organic light-emitting device 10 is configured in a full color display or a white light emitting display, the EML may be patterned into a red EML, a green EML, and a blue EML, according to a sub-pixel. In some embodiments, the EML may have a stacked structure of a red EML, a green EML, and a blue EML.

Here, the blue EML may be determined by referring to the aforementioned embodiment in connection with the emission layer. That is, the blue EML may be an EML including the first host, the second host, and the dopant emitting delayed fluorescence as described above.

The red EML and the green EML may include a known host and a known dopant.

The host of the red EML and the green EML may be at least one of, for example, TPBi, TBADN, ADN, CBP, CDBP, and TCP.

In some implementations, the host for the red and green emitting layer may include a compound represented by Formula 301 below:

Ar₃₀₁-[(L₃₀₁)_{xb1}-R₃₀₁]_{xb2} <Formula 301>

In Formula 301, Ar₃₀₁ may be selected from

naphthalene, heptalene, fluorene, spiro-fluorene, benzofluorene, dibenzofluorene, phenalene, phenanthrene, anthracene, fluoranthene, triphenylene, pyrene, chrysene, naphthacene, picene, perylene, pentaphene, and indenoanthracene; and

naphthalene, heptalene, fluorene, spiro-fluorene, benzofluorene, dibenzofluorene, phenalene, phenanthrene, anthracene, fluoranthene, triphenylene, pyrene, chrysene, naphthacene, picene, perylene, pentaphene, and indenoanthracene, each substituted with at least one of a deuterium atom, a halogen atom, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₆₀ aryl group, a C₆-C₆, aryloxy group, a C₆-C₆₀ arylthio group, a C₂-C₆₀ heteroaryl group, a C₈-C₆₀ monovalent non-aromatic condensed polycyclic group, a C₂-C₆₀ monovalent non-aromatic condensed heteropolycyclic group, —Si(Q₃₀₁)(Q₃₀₂)(Q₃₀₃) (wherein Q₃₀₁ to Q₃₀₃ may be each independently selected from a hydrogen, a C₁-C₆₀ alkyl group, a C₂-C₆₀ alkenyl group, a C₆-C₆₀ aryl group, and a C₂-C₆₀ heteroaryl group);

L₃₀₁ is the same as defined with respect to L₂₀₁;

R₃₀₁ may be selected from

a C₁-C₂₀ alkyl group and a C₁-C₂₀ alkoxy group;

a C₁-C₂₀ alkyl group and a C₁-C₂₀ alkoxy group, each substituted with at least one of a deuterium atom, a halogen atom, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group;

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazole group, and a triazinyl group; and

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group, each substituted with at least one of a deuterium atom, a halogen atom, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group;

xb1 may be selected from 0, 1, 2, and 3; and

xb2 may be selected from 1, 2, 3, and 4.

For example, in Formula 301,

L₃₀₁ may be selected from

a phenylene group, a naphthylene group, a fluorenylene group, a spiro-fluorenylene group, a benzofluorenylene group, a dibenzofluorenylene group, a phenanthrenylene group, an anthracenylene group, a pyrenylene group, and a chrysenylene group; and

a phenylene group, a naphthylene group, a fluorenylene group, a spiro-fluorenylene group, a benzofluorenylene group, a dibenzofluorenylene group, a phenanthrenylene group, an anthracenylene group, a pyrenylene group, and a chrysenylene group, each substituted with at least one of a deuterium atom, a halogen atom, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, and a chrysenyl group;

R₃₀₁ may selected from

a C₁-C₂₀ alkyl and C₁-C₂₀ alkoxy;

a C₁-C₂₀ alkyl group and a C₁-C₂₀ alkoxy group, each substituted with at least one of a deuterium atom, a halogen atom, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, and a chrysenyl group;

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, and a chrysenyl group; and

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, and a chrysenyl group, each substituted with at least one of a deuterium atom, a halogen atom, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, and a chrysenyl group.

For example, the host for the red or green emitting layer may include a compound represented by Formula 301A below:

Here, substituents in Formula 301A may be understood by referring to the description provided herein.

The compound represented by Formula 301 above may include at least one of Compounds H1 to H42 below:

In some implementations, the host for the red or green emitting layer may include at least one of Compounds H43 to H49 below:

A suitable dopant may be used as the dopant in the red EML and the green EML. An example thereof includes at least one of a fluorescent dopant and a phosphorescent dopant. An example of the phosphorescent dopant includes an organometallic complex including iridium (Ir), platinum (Pt), osmium (Os), rhenium (Re), titanium (Ti), zirconium (Zr), hafnium (Hf), or a combination of two or more of these elements.

In addition, an example of the known dopant in the red EML includes a compound below, such as Pt(II) octaethylporphine (PtOEP), tris(2-phenylisoquinoline)iridium (Ir(piq)₃), bis(2-(2′-benzothienyl)-pyridinato-N,C3′)iridium(acetylacetonate) (Btp₂Ir(acac)), 4-(dicyanomethylene)-2-methyl-6-[p-(dimethylamino)styryl]-4H-pyran (DCM), and 4-(dicyanomcthylene)-2-tert-butyl-6-(1,1,7,7,-tetramethyljulolidyl-9-enyl)-4H-pyran (DCJTB).

In addition, examples of the known dopant in the green EML include tris(2-phenylpyridine) iridium (Ir(ppy)₃), bis(2-phenylpyridineXacetylacetonato)iridium(III) (Ir(ppy)₂(acac)), tris(2-(4-tolyl)phenylpiridine)iridium (Ir(mppy)₃), and 10-(2-benzothiazolyl)-1,1,7,7-tetramethyl-2,3,6,7-tetrahydro-1H,5H,11H-[1]benzopyrano[6,7,8-ij]-quinolizin-11-one (C545T).

An amount of the dopant included in the EML may be about in a range of about 0.01 to about 15 parts by weight, based on 100 parts by weight of the host.

A thickness of the EML may be in a range of about 100 Å to about 1,000 Å, e.g., about 200 Å to about 600 Å. When the thickness of the EML is within these ranges, excellent emission characteristics may be obtained without a substantial increase in driving voltage.

In order to prevent diffusion of excitons or holes into an electron transport layer (ETL), a hole blocking layer (HBL) may be formed between the ETL and the EML by using a suitable method, such as vacuum deposition, spin coating, casting, or LB deposition. When the HBL is formed by vacuum deposition and spin coating, deposition and coating conditions for forming the HBL may vary according to a compound used to form the HBL, but in general, may be determined by referring to the deposition and coating conditions for forming the HIL. A suitable hole blocking material may be used as a material for forming the HBL. Examples thereof include an oxadiazole derivative, a triazole derivative, and a phenanthroline derivative. For example, the material for forming the HBL may be 2,9-dimethyl-4,7-diphenyl-1,10-phenanthroline (BCP). In some embodiments, the first host or the second host used in the EML may be used for forming the HBL.

A thickness of the HBL may be in a range of about 50 Å to about 1,000 Å, e.g., about 100 Å to about 300 Å. When the thickness of the HBL is within these ranges, the HBL may have excellent hole blocking characteristics without a substantial increase in driving voltage.

In addition, in order to prevent diffusion of excitons or holes into the HTL, an electron blocking layer (EBL) may be formed between the ETL and the EML by using a suitable methods, such as vacuum deposition, spin coating, casting, and LB deposition. The first host or the second host used in the EML may be also used in the EBL.

An electron transport layer (ETL) may be formed on the EML or EBL by using a suitable method, such as vacuum deposition, spin coating, or casting. When the ETL is formed by vacuum deposition and spin coating, deposition and coating conditions for forming the ETL may vary according to a compound used to form the ETL, but in general, may be determined by referring to the deposition and coating conditions for forming the HIL. A material for forming the ETL may stably transport electrons injected from an electron injection electrode (i.e., a cathode), and may be a suitable electron transport material.

Examples of a suitable electron transport material include a quinoline derivative, such as Alq₃, 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), BAlq (refer to Formula below), beryllium bis(benzoquinolin-10-olate (Bebq₂), 9,10-di(naphthalene-2-yl)anthracene (ADN), Compound 501, and Compound 502.

A thickness of the ETL may be in a range of about 100 Å to about 1,000 Å, e.g., about 150 Å to about 500 Å. When the thickness of the ETL is within the range described above, the ETL may have satisfactory electron transport characteristics without a substantial increase in a driving voltage.

In some embodiments, the ETL may include an electron transport organic compound and a metal-containing material. The metal-containing material may include a Li complex. Examples of the Li complex include lithium quinolate (LiQ) or Compound 503 below:

An electron injection layer (EIL), which facilitates electron injection from the cathode, may be stacked on the ETL. A suitable electron injection material may be used to form the EIL.

Examples of materials for forming the EIL include LiF, NaCl, CsF, Li₂O, and BaO. Deposition conditions for forming the EIL may vary according to a compound used to form the EIL, but in general, may be determined by referring to the deposition and coating conditions for forming the HIL.

A thickness of the EIL may be in a range of about 1 Å to about 100 Å, e.g., about 3 Å to about 90 Å. When the thickness of the EIL is within the range described above, the EIL may have satisfactory electron injection characteristics without a substantial increase in a driving voltage.

The second electrode 17 may be disposed on the organic layer 15. The second electrode 17 may be a cathode that is an electron injection electrode. A metal for forming the second electrode 17 may be a material having a low work function, such as a metal, an alloy, an electrically conductive compound, or a mixture thereof. For example, lithium (Li), magnesium (Mg), aluminum (Al), aluminum-lithium (Al—Li), calcium (Ca), magnesium-indium (Mg—In), or magnesium-silver (Mg—Ag) may be formed as a thin film to obtain a transmissive electrode. To manufacture a top emission type light-emitting device, a transmissive electrode formed using ITO or IZO may be formed.

The term “C₁-C₂₀ alkyl group” used herein may refer to a linear or branched alkyl group having 1 to 20 carbon atoms. Detailed examples thereof include a methyl group, an ethyl group, a propyl group, an isobutyl group, a sec-butyl group, a pentyl group, an iso-amyl group, and a hexyl group.

The term “C₁-C₂₀ alkoxy group: used herein may refer to a group represented by —OA (herein A is the unsubstituted C₁-C₂₀ alkyl group). Detailed examples thereof include a methoxy group, an ethoxy group, and an isopropyloxy group.

The term “C₆-C₄₀ aryl group” used herein may refer to a monovalent group having a carbocyclic aromatic system having 6 to 40 carbon atoms including at least one aromatic ring.

The term “C₆-C₄₀ arylene group” used herein may refer to a divalent group having a carbocyclic aromatic system having 6 to 40 carbon atoms including at least one aromatic ring. When the aryl group and the arylene group each include two or more rings, the rings may be fused to each other.

Examples of the C₆-C₄₀ aryl group include a phenyl group, a C₁-C₁₀ alkyl phenyl group (e.g., an ethylphenyl group), a C₁-C₁₀ alkylbiphenyl group (e.g., an ethyl biphenyl group), a halophenyl group (e.g., an o-, m- or p-fluorophenyl group, or a dichlorophenyl group), a dicyanophenyl group, a trifluoromethoxyphenyl group, an o-, m-, or p-tolyl group, an o-, m-, or p-cumenyl group, a mesityl group, a phenoxyphenyl group, a (α,α-dimethylbenzene)phenyl group, a (N,N′-dimethyl)aminophenyl group, a (N,N′-diphenyl)aminophenyl group, a pentalenyl group, an indenyl group, a naphthyl group, a halonaphthyl group (e.g., a fluoronaphthyl group), a C₁-C₁₀ alkylnaphthyl group (e.g., a methylnaphthyl group), a C₁-C₁₀ alkoxynaphthyl group (e.g., a methoxynaphthyl group), an anthracenyl group, an azulenyl group, a heptalenyl group, an acenaphthylenyl group, a phenalenyl group, a fluorenyl group, an anthraquinolyl group, a methylanthryl group, a phenanthryl group, a triphenylenyl group, a pyrenyl group, a chrysenyl group, an ethyl-chrysenyl group, a picenyl group, a perylenyl group, a chloroperylenyl group, a pentaphenyl group, a pentacenyl group, a tetraphenylenyl group, a hexaphenyl group, a hexacenyl group, a rubicenyl group, a coronenyl group, a trinaphthylenyl group, a heptaphenyl group, a heptacenyl group, a pyranthrenyl group, and an ovalenyl group.

The term “C₂-C₄₀ heteroaryl group” used herein may refer to a monovalent group having a system composed of one or more aromatic rings having at least one hetero atom selected from nitrogen (N), oxygen (O), phosphorous (P), silicon (Si), and sulfur (S) and carbon atoms as the remaining ring atoms. The term “C₂-C₃₀ heteroarylene group” used herein may refer to a divalent group having a system composed of one or more aromatic rings having at least one hetero atom selected from nitrogen (N), oxygen (O), phosphorous (P), silicon (Si), and sulfur (S) and carbon atoms as the remaining ring atoms. Here, if the heteroaryl group and the heteroarylene group include two or more rings, the rings may be fused to each other.

Examples of the C₂-C₄₀ heteroaryl group include a pyrazolyl group, an imidazolyl group, an oxazolyl group, a thiazolyl group, a triazolyl group, a tetrazolyl group, an oxadiazolyl group, a pyridinyl group, a pyridazinyl group, a pyrimidinyl group, a triazinyl group, a carbazolyl group, an indolyl group, a quinolinyl group, an isoquinolinyl group, a benzoimidazolyl group, an imidazopyridinyl group, and an imidazopyrimidinyl group.

The term “C₆-C₄₀ aryloxy group” used herein may refer to a group represented by —OA₂ (wherein, A₂ is the substituted or unsubstituted C₆-C₃₀ aryl group), and the term “C₆-C₄₀ arylthio group” used herein may refer to a group represented by —SA₃ (wherein, A₃ is the substituted or unsubstituted C₆-C₄₀ aryl group).

The term “monovalent non-aromatic condensed polycyclic group” used herein may refer to a monovalent group (e.g., a group having 8 to 40 carbon atoms) that has two or more tings condensed to each other, has carbon atoms only as a ring-forming atom, and has non-aromacity in the entire molecular structure. An example of a monovalent non-aromatic condensed polycyclic group is a fluorenyl group. The term “divalent non-aromatic condensed polycyclic group” used herein may refer to a divalent group having the same structure as the monovalent non-aromatic condensed polycyclic group.

The term “monovalent non-aromatic condensed heteropolycyclic group” used herein may refer to a monovalent group (e.g., a group having 2 to 60 carbon atoms) that has two or more tings condensed to each other, has N heteroatoms as a ring-forming atom selected from N, O, P, and S, in addition to C, and has non-aromacity in the entire molecular structure. An example of the monovalent non-aromatic condensed heteropolycyclic group is a carbazolyl group. The term “divalent non-aromatic condensed heteropolycyclic group” used herein may refer to a divalent group having the same structure as the monovalent non-aromatic condensed heteropolycyclic group.

The compound represented by Formula 1 and the compound represented by Formula 2 may be synthesized by using a suitable organic synthetic method.

Hereinafter, an organic light-emitting device according to an embodiment will be described in detail with reference to Synthesis Examples and Examples. Compounds used in Examples are shown in Table 1 below.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments.

Further, it will be understood that the embodiments are not limited to the particular details described in the Examples and Comparative Examples.

TABLE 1

| | |
|---|---|
| h1 (69) | |
| h2 (10) | |
| h3 (67) | |
| h4 (6) | |
| h5 (61) | |
| h6 (7) | |
| h7 (71) | |
| h8 (74) | |
| h9 (5) | |
| D1 (D2) | |
| D2 (D3) | |

```
  α-NPD
  TCTA
  TPBI
```

### Example 1

A glass substrate (a product of Corning Co., Ltd) on which an ITO anode was formed was cut to a size of 50 mm×50 mm×0.5 mm, sonicated by using acetone isopropyl alcohol and pure water each for 15 minutes, and cleansed by the exposure to UV ozone for 30 minutes. a-NPD was vacuum deposited on the ITO glass substrate to form an HIL having at thickness of 600 Å, and then, TCTA was vacuum deposited on the HIL to form an HTL having a thickness of 400 Å. A host, i.e., a combination of Compound h1 and Compound h2, in which a weight ratio of Compound h1 to Compound h2 was 30:70, and a blue dopant, i.e., Compound D1, were co-deposited at a weight ratio of the host to the dopant was 94:6 on the HTL to form an EML having a thickness of 300 Å. TPBi was vacuum deposited on the EML to form an ETL having a thickness of 300 Å. LiF was vacuum deposited on the ETL to form an EIL having a thickness of 10 Å, and then, Al was vacuum deposited thereon to form a cathode having a thickness of 2,000 Å, thereby completing manufacturing of an organic light-emitting device.

### Example 2

An organic light-emitting device was manufactured in the same manner as in Example 1, except that in forming the EML, a combination of Compound h3 and Compound h4 was used as the host at a weight ratio of 30:70 instead of using the combination of Compound h1 and Compound h2 as the host at a weight ratio of 30:70.

### Example 3

An organic light-emitting device was manufactured in the same manner as in Example 1, except that in forming the EML, a combination of Compound h5 and Compound h6 was used as the host at a weight ratio of 70:30 instead of using the combination of Compound h1 and Compound h2 as the host at a weight ratio of 30:70.

### Example 4

An organic light-emitting device was manufactured in the same manner as in Example 1, except that in forming the EML, a combination of Compound h7 and Compound h2 was used as the host at a weight ratio of 30:70 instead of using the combination of Compound h1 and Compound h2 as the host at a weight ratio of 30:70.

### Example 5

An organic light-emitting device was manufactured in the same manner as in Example 1, except that in forming the EML, a combination of Compound h8 and Compound h2 was used as the host at a weight ratio of 30:70 instead of using the combination of Compound h1 and Compound h2 as the host at a weight ratio of 30:70.

### Example 6

An organic light-emitting device was manufactured in the same manner as in Example 1, except that in forming the EML, Compound D2 was used instead of Compound D1 as the dopant used in the EML.

### Example 7

An organic light-emitting device was manufactured in the same manner as in Example 2, except that in forming the EML, Compound D2 was used instead of Compound D1 as the dopant used in the EML.

### Example 8

An organic light-emitting device was manufactured in the same manner as in Example 3, except that in forming the EML, Compound D2 was used instead of Compound D1 as the dopant used in the EML.

### Example 9

An organic light-emitting device was manufactured in the same manner as in Example 4, except that in forming the EML, Compound D2 was used instead of Compound D1 as the dopant used in the EML.

### Example 10

An organic light-emitting device was manufactured in the same manner as in Example 5, except that in forming the EML, Compound D2 was used instead of Compound D1 as the dopant used in the EML.

### Comparative Example 1

An organic light-emitting device was manufactured in the same manner as in Example 1, except that in forming the EML, Compound h9 was used as the host instead of the combination of Compound h1 and Compound h2 as the host at a weight ratio of 30:70.

### Comparative Example 2

An organic light-emitting device was manufactured in the same manner as in Example 1, except that in forming the EML, Compound h6 was used as the host instead of the combination of Compound h1 and Compound h2 as the host at a weight ratio of 30:70.

### Comparative Example 3

An organic light-emitting device was manufactured in the same manner as in Comparative Example 1, except that in forming the EML, Compound D2 was used instead of Compound D as the dopant used in the EML.

### Comparative Example 4

An organic light-emitting device was manufactured in the same manner as in Comparative Example 2, except that in forming the EML, Compound D2 was used instead of Compound D1 as the dopant used in the EML.

### Evaluation Example

External quantum efficiencies of the organic light-emitting devices manufactured according to Examples 1 to 10 and Comparative Examples 1 to 4 were evaluated at a current density of 0.1 mA/cm² and at a current density of 10 mA/cm². Results thereof are shown in Table 2 below.

TABLE 2

| | | | EQE | EQE |
|---|---|---|---|---|
| Device | Host | Dopant | (0.1 mA/cm²) | (10 mA/cm²) |
| Example 1 | H1:H2 (30:70) | D1 | 12% | 10.1% |
| Example 2 | H3:H4 (30:70) | D1 | 11.3% | 9.5% |
| Example 3 | H5:H6 (70:30) | D1 | 13% | 10.5% |
| Example 4 | H7:H2 (30:70) | D1 | 10.8% | 7.5% |
| Example 5 | H8:H2 (30:70) | D1 | 13.2% | 10.1% |
| Example 6 | H1:H2 (30:70) | D2 | 7.5% | 5.8% |
| Example 7 | H3:H4 (30:70) | D2 | 8.8% | 6.9% |
| Example 8 | h5:h6 (70:30) | D2 | 9.1% | 8.5% |
| Example 9 | H7:H2 (30:70) | D2 | 8.0% | 7.1% |
| Example 10 | H8:H2 (30:70) | D2 | 9.8% | 8.0% |
| Comparative | H9 | D1 | 3.8% | 1.2% |
| Example 1 | | | | |
| Comparative | H6 | D1 | 10.5% | 4.0% |
| Example 2 | | | | |
| Comparative | H9 | D2 | 4.0% | 2.0% |
| Example 3 | | | | |
| Comparative | H6 | D2 | 6.7% | 4.3% |
| Example 4 | | | | |

It can be seen in Table 2 that at a current density of 0.1 mA/cm² and at a current density of 10 mA/cm², the external quantum efficiencies of the organic light-emitting devices of Examples 1 to 10 were all higher than those of the organic light-emitting devices of Comparative Examples 1 to 4. From these results, it may be confirmed that efficiency and roll-off characteristics of the organic light-emitting devices of Examples 1 to 10 were higher than those of the organic light-emitting devices of Comparative Examples 1 to 4.

An organic light-emitting device according to exemplary embodiments includes an emission layer formed using a delayed fluorescent dopant and a mixed host. Due to the use of such an emission layer, the organic light-emitting device may have high efficiency and improved efficiency roll-off characteristics.

By way of summation and review, the materials for forming the emission layer may be classified as a fluorescent material using a singlet state (S1) and a phosphorescent material using a triplet state (T1), according to an emission mechanism of the materials. These materials may be used alone or doped in a host material, so as to form the emission layer. A statistical generation ratio of a singlet exciton to a triplet exciton in the emission layer is about 1:3.

In recent years, an organic light-emitting device using delayed fluorescence has been actively developed other than an organic light-emitting device using fluorescence emitted from an excited singlet state S1 or phosphorescence emitted from an excited triplet state T1. The term “delayed fluorescence refers” to fluorescent emission created by activating an energy up-conversion from the excited triplet state T1 to the excited singlet state S1 with a thermal energy. Due to the emission from the singlet state S1 via the triplet state T1, delayed fluorescence generally has a long lifespan.

In terms of the energy up-conversion from the excited triplet state T1 to the excited singlet state S1, it is better for a luminescent material to have a small difference between the energy level of the triplet state T1 and the energy level of the single state S1. In addition, in order to convert as much of the excited triplet state T1 as possible into the excited singlet state S1 of a luminescent material as a dopant, the triplet energy level of a host is also a factor to be considered. However, in the case of a host having a high triplet energy level, due to its great band gap energy, injection of charge may not be effectively performed from adjacent layers, and due to its short conjugation length, charge transport characteristics may be relatively degraded.

Embodiments provide an organic light-emitting device including an emission layer emitting blue delayed fluorescence with high efficiency and improved roll-off characteristics.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An organic light-emitting device, comprising:
a first electrode;
a second electrode facing the first electrode; and
an emission layer between the first electrode and the second electrode, the emission layer including a dopant, a first host, and a second host,
wherein the dopant is a material emitting delayed fluorescence, the first host is a compound represented by Formula 1 below, and the second host includes a compound represented by any one of Formulae 2-1, 2-2, and 2-3 below:
wherein, in Formulae 2-1, 2-2, and 2-3,
X is N, S, or O,
X₂ is NR₆, O, or S,
X₃ is NR₉, O, or S,
Y₁ is CR₁₂ or N,
Y₂ is CR₁₃ or N,
Y₃ is CR₁₄ or N, and
Y₄ is CR₁₅ or N, wherein at least one of Y₁, Y₂, Y₃, and Y₄ is N,
R₁ to R₁₅ are each independently selected from
a deuterium atom, a halogen atom, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₂-C₂₀ alkenyl group, a C₂-C₂₀ alkynyl group, a C₁-C₂₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₄₀ aryl group, a C₂-C₄₀ heteroaryl group, a C₅-C₄₀ aryloxy group, a C₅-C₄₀ arylthio group, —N(Q₁)(Q₂) (wherein Q₁ and Q₂ are each independently a C₆-C₄₀ aryl group), —P(═O)(Q₃)(Q₄) (wherein Q₃ and Q₄ are each independently a C₆-C₄₀ aryl group), —Si(Q₅)(Q₆)(Q₇) (wherein Q₅, Q₆, and Q₇ are each independently a C₆-C₄₀ aryl group), a C₈-C₄₀ non-aromatic condensed polycyclic group, and a C₂-C₆₀ non-aromatic condensed heteropolycyclic group;
a C₁-C₄₀ alkyl group, a C₂-C₄₀ alkenyl group, a C₂-C₄₀ alkynyl group, and a C₁-C₄₀ alkoxy group, each substituted with at least one of a deuterium atom, a halogen atom, a hydroxyl group, a cyano group, a nitro group, an amino group, an amidino group, a hydrazine group, a hydrazone group, a carboxylic acid or a salt thereof, a sulfonic acid or a salt thereof and a phosphoric acid or a salt thereof, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₅-C₄₀ aryl group, a C₂-C₄₀ heteroaryl group, a C₅-C₄₀ aryloxy group, and a C₅-C₄₀ arylthio group; and
a C₃-C₁₀ cycloalkyl group, a C₃-C₁₀ heterocycloalkyl group, a C₃-C₁₀ cycloalkenyl group, a C₃-C₁₀ heterocycloalkenyl group, a C₅-C₄₀ aryl group, a C₂-C₄₀ heteroaryl group, a C₈-C₄₀ non-aromatic condensed polycyclic group, a C₂-C₆₀ non-aromatic condensed heteropolycyclic group, a C₅-C₄₀ aryloxy group, and a C₅-C₄₀ arylthio group, each substituted with at least one of a deuterium atom, a halogen atom, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₂-C₂₀ alkenyl group, a C₂-C₂₀ alkynyl group, a C₁-C₂₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₅-C₄₀ aryl group, a C₂-C₄₀ heteroaryl group, a C₅-C₄₀ aryloxy group, and a C₅-C₄₀ arylthio group, wherein a plurality of R₂ to R₃ are independent from each other,
L₁ to L₇ are each independently selected from a direct bond, —O—, a C₃-C₁₀ cycloalkylene group, a C₆-C₄₀ arylene group, a C₂-C₄₀ heteroarylene group, a C₅-C₄₀ divalent non-aromatic condensed polycyclic group, or a C₂-C₆₀ divalent non-aromatic condensed heteropolycyclic group; and
a C₃-C₁₀ cycloalkylene group, a C₆-C₄₀ arylene group, a C₂-C₄₀ heteroarylene group, a C₈-C₄₀ divalent non-aromatic condensed polycyclic group, and a C₂-C₆₀ divalent non-aromatic condensed heteropolycyclic group, each substituted with at least one of a deuterium atom, a halogen atom, a hydroxyl group, a cyano group, a nitro group, an amino group, an amidino group, a hydrazine group, a hydrazone group, a carboxylic acid or a salt thereof, a sulfonic acid or a salt thereof and a phosphoric acid or a salt thereof, a C₁-C₂₀ alkyl group, a C₂-C₂₀ alkenyl group, a C₂-C₂₀ alkynyl group, a C₁-C₂₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₅-C₄₀ aryl group, a C₂-C₄₀ heteroaryl group, a C₅-C₄₀ aryloxy group, and a C₈-C₄₀ arylthio group, wherein a plurality of L₂ to L₃ are independent from each other,
a₁, b₁, and c₁ are each independently an integer of 0 to 3,
a₁ and a₂ are 0 in a case of X being O or S, and a₂ is 1 in a case of X being N,
b and c are each independently an integer of 0 to 4, and
d to g are each independently an integer of 0 to 3.

2. The organic light-emitting device as claimed in claim 1, wherein R₁ to R₁₁ are each independently selected from a methyl group, an ethyl group, a propyl group, a butyl group, a pentyl group, a hexyl group, a heptyl group, a pyrrolyl group, a furyl group, a pyrazolyl group, an imidazolyl group, an oxazolyl group, an isoxazolyl group, a triazolyl group, a tetrazolyl group, an oxadiazolyl group, a pyridyl group, a pyrimidinyl group, a pyrazinyl group, a pyridazinyl group, a triazinyl group, a pyranyl group, a thiophenyl group, a thiazolyl group, an isothiazolyl group, a thiopyranyl group, an indolyl group, an isoindolyl group, an indolizinyl group, a benzofuryl group, an isobenzofuryl group, an indazolyl group, a benzimidazolyl group, a bcnzoxazolyl group, a benzisoxazolyl group, an imidazopyridyl group, a purinyl group, a quinolyl group, an isoquinolyl group, a phthalazinyl group, a quinazolinyl group, a quinoxalinyl group, a naphthyridinyl group, a cinnolinyl group, a benzothiophenyl group, a benzothiazolyl group, a carbazolyl group, a benzocarbazolyl group, a pyridoindolyl group, a dibenzofuryl group, a phenanthridinyl group, a benzoquinolyl group, a phenazinyl group, a dibenzosilolyl group, a dibenzothiophenyl group, a benzocarbazolyl group, —N(Q₁)(Q₂) (wherein Q₁ and Q₂ are each independently a C₆-C₄₀ aryl group), —N(Q₁)(Q₂) (wherein Q₁ and Q₂ are each independently a C₆-C₄₀ aryl group), —P(═OX)Q₃)(Q₄) (wherein Q₃ and Q₄ are each independently a C₆-C₄₀ aryl group), —Si(Q₅)(Q₆)(Q₇) (wherein Q₅, Q₆, and Q₇ are each independently a C₆-C₄₀ aryl group), a C₈-C₄₀ monovalent non-aromatic condensed polycyclic group, and a C₂-C₆₀ monovalent non-aromatic condensed heteropolycyclic group;
a methyl group, an ethyl group, a propyl group, a butyl group, a pentyl group, a hexyl group, a heptyl group, an octyl group, a nonyl group, and a decyl group, each substituted with at least one of a deuterium atom, a halogen atom, a hydroxyl group, a cyano group, a nitro group, an amino group, a C₆-C₄₀ aryl group, and a C₆-C₄₀ heteroaryl group; and
a pyrrolyl group, a furyl group, a pyrazolyl group, an imidazolyl group, an oxazolyl group, an isoxazolyl group, a triazolyl group, a tetrazolyl group, an oxadiazolyl group, a pyridyl group, a pyrimidinyl group, a pyrazinyl group, a pyridazinyl group, a triazinyl group, a pyranyl group, a thiophenyl group, a thiazolyl group, an isothiazolyl group, a thiopyranyl group, an indolyl group, an isoindolyl group, an indolizinyl group, a benzofuryl group, an isobenzofuryl group, an indazolyl group, a benzimidazolyl group, a benzoxazolyl group, a benzisoxazolyl group, an imidazopyridyl group, a purinyl group, a quinolyl group, an isoquinolyl group, a phthalazinyl group, a quinazolinyl group, a quinoxalinyl group, a naphthyridinyl group, a cinnolinyl group, a benzothiophenyl group, a benzothiazolyl group, a carbazolyl group, a benzocarbazolyl group, a pyridoindolyl group, a dibenzofuryl group, a phenanthridinyl group, a benzoquinolyl group, a phenazinyl group, a dibenzosilolyl group, a dibenzothiophenyl group, a benzocarbazole group, —N(Q₁)(Q₂) (wherein Q₁ and Q₂ are each independently a C₆-C₄₀ aryl group), —P(═O)(Q₃)(Q₄) (wherein Q₃ and Q₄ are each independently a C₆-C₄₀ aryl group), —Si(Q₅)(Q₆)(Q₇) (wherein Q₅, Q₆, and Q₇ are each independently a C₆-C₄₀ aryl group), a C₈-C₄₀ monovalent non-aromatic condensed polycyclic group, and a C₂-C₆₀ monovalent non-aromatic condensed heteropolycyclic group, each substituted with at least one of a deuterium atom, a halogen atom, a hydroxyl group, a cyano group, a nitro group, an amino group, a carboxylic acid or a salt thereof, a sulfonic acid or a salt thereof and a phosphoric acid or a salt thereof, a C₁-C₁₀ alkyl group, a C₂-C₁₀ alkenyl group, a C₂-C₁₀ alkynyl group, a C₁-C₁₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₆-C₃₀ aryl group, a C₄-C₃₀ heteroaryl group, a C₅-C₃₀ aryloxy group, a C₅-C₃₀ arylthio group, and —Si(Q₃₁)(Q₃₂)(Q₃₃) (wherein Q₃₁ to Q₃₃ are each independently selected from a hydrogen, a C₁-C₁₀ alkyl group, a C₁-C₁₀ alkoxy group, a C₆-C₂₀ aryl group).

3. The organic light-emitting device as claimed in claim 1, wherein R₁ to R₁₁ are each independently selected from —N(Q₁)(Q₂) (wherein Q₁ and Q₂ are a phenyl group or a phenyl group substituted with a C₆-C₄₀ aryl group) and groups represented by Formulae 3A to 3O below:
in Formula 3A to 3O,
Z₁₁ to Z₁₈ are each independently selected from a deuterium atom, a halogen atom, a hydroxyl group, a cyano group, a nitro group, an amino group, a carboxylic acid or a salt thereof, a sulfonic acid or a salt thereof and a phosphoric acid or a salt thereof, a C₁-C₂₀ alkyl group, a C₁-C₂₀ alkoxy group, a C₆-C₄₀ aryl group, a C₂-C₄ heteroaryl group, a C₈-C₄₀ monovalent non-aromatic condensed polycyclic group, and a C₂-C₆₀ monovalent non-aromatic condensed heteropolycyclic group;
a C₁-C₂₀ alkyl group and a C₁-C₂₀ alkoxy group, each substituted with at least one of a deuterium atom and a halogen atom; and
a C₆-C₄₀ aryl group, a C₂-C₄₀ heteroaryl group, a C₈-C₄₀ monovalent non-aromatic condensed polycyclic group, and a C₂-C₆₀ monovalent non-aromatic condensed heteropolycyclic group, each substituted with at least one of a deuterium atom, a halogen atom, C₁-C₂₀ alkyl group, a C₁-C₂₀ alkoxy group, a C₆-C₂₀ aryl group, and a C₂-C₂₀ heteroaryl group;
A₁ to Ar₉ are each independently selected from a C₆-C₄₀ aryl group and a C₂-C₄₀ heteroaryl group; and
a C₆-C₄₀ aryl group and a C₂-C₄₀ heteroaryl group, each substituted with at least one of a deuterium atom, a halogen atom, a C₁-C₂₀ alkyl group, a C₁-C₂₀ alkoxy group, a C₆-C₂₀ aryl group, a C₂-C₂₀ heteroaryl group, a C₈-C₄₀ monovalent non-aromatic condensed polycyclic group, a C₂-C₄₀ monovalent non-aromatic condensed heteropolycyclic group, and —N(Q₁)(Q₂) (wherein Q₁ and Q₂ are each independently a C₆-C₄₀ aryl group),
Ar₁ and Ar₂ may be connected to each other to form a condensed ring;
p1 to p3 are each independently an integer of 0 to 4,
p4 is an integer of 0 to 5,
p5 is an integer of 0 to 4,
p6 is an integer of 0 to 4,
p7 is an integer of 0 to 3, and
* indicates a binding site.

4. The organic light-emitting device as claimed in claim 3, wherein
Z₁₁ to Z₁₈ are each independently a cyano group, a methyl group, an ethyl group, a t-butyl group, a phenyl group, or a naphthyl group,
Ar₁ to Ar₉ are each independently selected from a phenyl group, a dibenzofuryl group, and a dibenzothiophenyl group; and
a phenyl group, a dibenzofuryl group, and a dibenzothiophenyl group, each substituted with at least one of —NQ₁Q₂(wherein Q₁ and Q₂ are each independently a C₆-C₄₀ aryl group), a C₆-C₄₀ heteroaryl group, a C₈-C₄₀ monovalent non-aromatic condensed polycyclic group, and a C₂-C₄₀ monovalent non-aromatic condensed heteropolycyclic group, wherein Ar₁ and Ar₂ may be connected with each other to form a condensed ring.

5. The organic light-emitting device as claimed in claim 1, wherein
R₁ to R₁₁ are each independently selected from groups represented by Formulae 4A to 4AI below:

6. The organic light-emitting device as claimed in claim 1, wherein L₁ to L₇ are each independently selected from cyclobutylene, adamantylene, phenylene, pentalenylene, indenylene, naphthylene, azulenylene, heptalenylene, indacenylene, acenaphthylene, fluorenylene, spiro-fluorenylene, benzofluorenylene, dibenzofluorenylene, phenalenylene, phenanthrenylene, anthracenylene, fluoranthenylene, triphenylenylene, pyrenylene, chrysenylene, naphthacenylene, picenylene, perylenylene, pentaphenylene, hexacenylene, pentacenylene, rubicenylene, coronenylene, ovalenylene, pyrrolylene, thiophenylene, furanylene, imidazolylene, pyrazolylene, thiazolylene, isothiazolylene, oxazolylene, isooxazolylene, pyridylene, pyrazinylene, pyrimidinylene, pyridazinylene, isoindolylene, indolylene, indazolylene, purinylene, quinolinylene, isoquinolinylene, benzoquinolinylene, phthalazinylene, naphthyridinylene, quinoxalinylene, quinazolinylene, cinnolinylene, carbazolylene, phenanthridinylene, acridinylene, phenanthrolinylene, phenazinylene, benzoimidazolylene, benzofuranylene, benzothiophenylene, isobenzothiazolylene, benzooxazolylene, isobenzooxazolylene, triazolylene, tetrazolylene, oxadiazolylene, triazinylene, dibenzofuranylene, dibenzothiophenylene, benzocarbazolylene, dibenzocarbazolylene, thiadiazolylene, and imidazopyridylene; and
phenylene, pentalenylene, indenylene, naphthylene azulenylene, heptalenylene, indacenylene, acenaphthylene, fluorenylene, spiro-fluorenylene, benzofluorenylene, dibenzofluorenylene, phenalenylene, phenanthrenylene, anthracenylene, fluoranthenylene, triphenylenylene, pyrenylene, chrysenylene, naphthacenylene, picenylene, perylenylene, pentaphenylene, hexacenylene, pentacenylene, rubicenylene, coronenylene, ovalenylene, pyrrolylene, thiophenylene, furanylene, imidazolylene, pyrazolylene, thiazolylene, isothiazolylene, oxazolylene, isoxazolylene, pyridylene, pyrazinylene, pyrimidinylene, pyridazinylene, isoindolylene, indolylene, indazolylene, purinylene, quinolinylene, isoquinolinylene, benzoquinolinylene, phthalazinylene, naphthyridinylene, quinoxalinylene, quinazolinylene, cinnolinylene, carbazolylene, phenanthridinylene, acridinylene, phenanthrolinylene, phenazinylene, benzoimidazolylene, benzofuranylene, benzothiophenylene, isobenzothiazolylene, benzooxazolylene, isobenzooxazolylene, triazolylene, tetrazolylene, oxadiazolylene, triazinylene, dibenzofuranylene, dibenzothiophenylene, benzocarbazolylene, dibenzocarbazolylene, thiadiazolylene, and imidazopyridylene, each substituted with at least one of a deuterium atom, a halogen atom, a hydroxyl group, a cyano group, an amino group, a C₁-C₂₀ alkyl group, a C₂-C₂₀ alkenyl group, a C₂-C₂₀ alkynyl group, a C₁-C₂₀ alkoxy group, a C₃-C₁₀ cycloalkyl group, a C₃-C₁₀ heterocycloalkyl group, a C₃-C₁₀ cycloalkenyl group, a C₃-C₁₀ heterocycloalkenyl group, a C₅-C₄₀ aryl group, a C₂-C₄₀ heteroaryl group, a C₅-C₄₀ aryloxy group, and a C₅-C₄₀ arylthio group.

7. The organic light-emitting device as claimed in claim 1, wherein
L₁ to L₇ are each independently selected from groups represented by Formulae 5A to 5D below:
in Formulae 5A to 5D,
Z₂₁ to Z₂₅ are each independently at least one of a deuterium atom, a halogen atom, a hydroxyl group, a cyano group, a nitro group, an amino group, a carboxylic acid or a salt thereof, a sulfonic acid or a salt thereof and a phosphoric acid or a salt thereof, a C₁-C₂₀ alkyl group, a C₁-C₂₀ alkoxy group, a C₆-C₄₀ aryl group, a C₂-C₄₀ heteroaryl group, a C₈-C₄₀ monovalent non-aromatic condensed polycyclic group, and a C₂-C₄₀ monovalent non-aromatic condensed heteropolycyclic group;
a C₁-C₂₀ alkyl group and a C₁-C₂₀ alkoxy group, each substituted with at least one of a deuterium atom and a halogen atom; and
a C₆-C₄₀ aryl group, a C₂-C₄₀ heteroaryl group, a C₈-C₄₀ monomer non-aromatic condensed polycyclic group, and a C₂-C₄₀ monomer non-aromatic condensed heteropolycyclic group, each substituted with at least one of a deuterium atom, a halogen atom, C₁-C₂₀ alkyl group, a C₁-C₂₀ alkoxy group, a C₆-C₂₀ aryl group, and a C₂-C₂₀ heteroaryl group;
q1 is an integer of 0 to 4,
q2 is an integer of 0 to 3,
q3 is an integer of 0 to 2,
q4 and q5 are each independently an integer of 0 to 5, and
* indicates a binding site.

8. The organic light-emitting device as claimed in claim 7, wherein
Z₂₁ to Z₂₅ are each independently a methyl group or a carbazolyl group.

9. The organic light-emitting device as claimed in claim 1, wherein
L₁ to L₇ are each independently selected from groups represented by Formulae 6A to 6I below:
wherein * indicates a binding site.

10. The organic light-emitting device as claimed in claim 1, wherein the compound of Formula 1 may be represented by any one of Compounds below:

11. The organic light-emitting device as claimed in claim 1, wherein:
the second host includes the compound represented by Formula 2-1, and
the compound of Formula 2-1 is represented by any one of Compounds below:

12. The organic light-emitting device as claimed in claim 1, wherein:
the second host includes a compound of Formula 2-2, and
the compound of Formula 2-2 is represented by any one of Compounds below:

13. The organic light-emitting device as claimed in claim 1, wherein:
the second host includes the compound of Formula 2-3, and
the compound of Formula 2-3 is represented by any one of Compounds below:

14. The organic light-emitting device as claimed in claim 4, wherein the weight ratio of the first host to the second host is in a range of about 10:90 to about 90:10.

15. The organic light-emitting device as claimed in claim 1, wherein the dopant includes a compound represented by any one of Formulae 3-1 to Formula 3-4 below:
[EDG]ₘ-{Aₙ-[EWG]ₒ}ₚ <Formula 3-1>
[EWG]_{q}-{Aᵣ-[EDG]ₛ}ₜ <Formula 3-2>
[EWG]-A-[EDG]-B-[EWG] <Formula 3-3>
[EDG]-A-[EWG]-B-[EDG] <Formula 3-4>
wherein, in Formulae 3-1 to 3-4,
EDG refers to an electron donating group, and
the electron donating group (EDG) is —C≡C—R, —O—R, —N(R)H, —N(R)₂, —NH2, —OH or —NH(CO)—R, a substituted or unsubstituted C₁-C₂ alkyl group, a C₆-C₃₀ aryl group, a substituted or unsubstituted C₆-C₃₀ monomer non-aromatic condensed polycyclic group, a furanyl group or a derivative thereof, a benzofuranyl group or a derivative thereof, a dibenzofuranyl group or a derivative thereof, a thiophenyl group or a derivative thereof, a benzothiophenyl group or a derivative thereof, a dibenzothiophenyl group or a derivative thereof, a fluorenyl group or a derivative thereof, a spiro-fluorenyl group or a derivative thereof, or an indenyl group or a derivative thereof,
EWG refers to an electron withdrawing group, and
the electron withdrawing group (EWG) is —X(—F, —Cl, —Br, —I), —C(═O)H, —C(═O)—R, —C(═O)O—R, —C(═O)OH, —(C═O)Cl, —CF₃, —C≡N, —S(═O)₂—OH, —S(═O)₂—O—R, —N⁺H₃, —N⁺R₃, —(N⁺═O)═O⁻, a substituted or unsubstituted N-containing 5-membered ring group of a C₂-C₃₀ group, a substituted or unsubstituted N-containing 6-membered ring group of a C₂-C₃₀ group, a substituted or unsubstituted N-containing 5-membered group of a C₁₀-C₃₀ group that is fused with a 6-membered ring, or a substituted or unsubstituted N-containing 6-membered ring of a C₁₀-C₃₀ group that is fused with a 6-membered ring, wherein R is each independently selected from a hydrogen, a deuterium atom, a C₆-C₃₀ aryl group, a C₂-C₃₀ heteroaryl group; and a C₆-C₃₀ aryl group or a C₂-C₃₀ heteroaryl group, each substituted with a C₁-C₁₀ alkyl group, a C₁-C₁₀ alkoxy group, a C₆-C₃₀ aryl group, a C₂-C₃₀ heteroaryl group, a C₆-C₃₀ aryloxy group, or a C₆-C₃₀ arylthio group,
A and B are each independently single bond, a C₁-C₃₀ alkylene group, or a C₆-C₃₀ arylene group, and
m, q, o, s, p, and t are each independently integers of 1 to 10, and n and r are 0 or 1.

16. The organic light-emitting device as claimed in claim 1, wherein the dopant comprises any one of Compounds below:

17. The organic light-emitting device as claimed in claim 1, further comprising a hole transport region between the first electrode and the emission layer.

18. The organic light-emitting device as claimed in claim 1, further comprising an electron transport region between the second electrode and the emission layer.

19. The organic light-emitting device as claimed in claim 17, wherein the hole transport region includes at least one of an electron blocking layer, a hole transport layer, and a hole injection layer.

20. The organic light-emitting device as claimed in claim 18, wherein the electron transport region includes at least one of a hole blocking layer, an electron transport layer, and electron injection layer.
